(19) United States
(12) Patent Application Publication
(10) Pub. No.: US 2026/0090438 A1
(43) Pub. Date: Mar. 26, 2026

(54) SUBSTRATE BONDING DEVICE, SUBSTRATE PROCESSING SYSTEM, AND SUBSTRATE BONDING METHOD

(71) Applicant: TOKYO OHKA KOGYO CO., LTD., Kawasaki-shi (JP)

(72) Inventors: Yubun KIKUCHI, Kawasaki-shi (JP); Yoshihiro YAMADA, Kawasaki-shi (JP); Ryuma MIZUSAWA, Kawasaki-shi (JP)

(21) Appl. No.: 18/994,794

(22) PCT Filed: Jul. 7, 2023
(86) PCT No.: PCT/JP2023/025230

§ 371 Date: Dec. 12, 2025

(30) Foreign Application Priority Data
Jul. 21, 2022 (JP) 2022-116368

(51) Int. Cl. H01L 23/00

(52) U.S. Cl. CPC H10W 72/0711; H10W 72/073; H10W 72/07141; H10W 72/07331; H10W 72/07332

(57) ABSTRACT

[Problem] To prevent formation of residues of a second adhesive on a semiconductor wafer during debonding by ensuring a low adhesion between a second support and the semiconductor wafer to prevent the two from adhering together too firmly while preventing bonding failure of a first support, even when the second support is bonded to a second surface of the semiconductor wafer.

[Means to Solve Problem] A substrate bonding device 1 includes: a bonder 10 that bonds a second support 110 to a second surface Sb, which is on an opposite side to a first surface Sa of a semiconductor wafer W, via a second adhesive 60, with the first surface Sa having a first support 100 bonded thereto at a first temperature via a first adhesive 50; and a heater 20 that heats one or both of the second support 110 and the semiconductor wafer W at a second temperature that is lower than the first temperature.

### TECHNICAL FIELD

The present invention relates to a substrate bonding device, a substrate processing system, and a substrate bonding method.

The present application claims priority to Japanese Patent Application No. 2022-116368, filed Jul. 21, 2022, the contents of which are incorporated herein by reference.

### BACKGROUND ART

As electronic devices face demands for miniaturization, weight reduction, and thickness reduction, semiconductor devices within these electronic devices are also required to be thinner. In order to reduce the thickness of semiconductor devices, it is necessary to reduce the thickness of the semiconductor wafer that constitutes the device. However, as the wafer's thickness is reduced, its strength is also reduced, making it susceptible to breakage, which in turn diminishes the ease of handling the semiconductor wafer. To address this, a method has been proposed. In this method, a plate-shaped first support is bonded to the first surface of a semiconductor wafer, where circuit electrodes, electronic circuits, and other components are formed, to create a first laminate. With the semiconductor wafer in this first laminate state, the second surface, which is on the opposite side to the first surface, is ground to thin the semiconductor wafer. Subsequently, a second laminate is created by bonding a plate-shaped second support to the second surface (that is, the surface that has been ground), which is on the opposite side to the first surface, thereby reinforcing the strength of the semiconductor wafer (for example, see Patent Literature 1).

### CITATION LIST

### Patent Literature

[Patent Literature 1] Japanese Unexamined Patent Application, First Publication No. H08-031778

### SUMMARY OF INVENTION

### Technical Problem

A first support is bonded to a first surface of a semiconductor wafer via a first adhesive, and then a second support is bonded to a second surface of the semiconductor wafer via a second adhesive. The bonding of the first support and the bonding of the second support are performed by applying heat to both the semiconductor wafer and the first support (second support). In such a case, when bonding the second support, the first support is bonded to the semiconductor wafer via the first adhesive. Therefore, if the temperature at which the second support is bonded to the second surface of the semiconductor wafer is higher than the temperature at which the first support is bonded to the first surface, the first adhesive may soften, which may lead to a bonding failure of the first support. Also, if the adhesion is high between the second support and the semiconductor wafer, the two may adhere together too firmly, and when the second support is debonded from the semiconductor wafer, residues of the second adhesive may be formed on the semiconductor wafer, which is undesirable.

An object of the present invention is to provide a substrate bonding device, a substrate processing system, and a substrate bonding method capable of preventing the formation of residues of a second adhesive on a semiconductor wafer during debonding, by ensuring a low adhesion between a second support and the semiconductor wafer to prevent the two from adhering together too firmly while preventing bonding failure of a first support, even when the second support is bonded to a second surface of the semiconductor wafer.

### Means for Solving Problem

A substrate bonding device according to an aspect of the present invention includes: a bonder that bonds a second support to a second surface, which is an opposite side to a first surface of a semiconductor wafer, via a second adhesive, with the first surface of the semiconductor wafer having a first support bonded thereto at a first temperature via a first adhesive; and a heater that heats one or both of the second support and the semiconductor wafer at a second temperature that is lower than the first temperature.

A substrate processing system according to an aspect of the present invention includes: a bonder that bonds a second support to a second surface, which is on an opposite side to a first surface of a semiconductor wafer, via a second adhesive, with the first surface of the semiconductor wafer having a first support bonded thereto at a first temperature via a first adhesive; a heater that heats one or both of the second support and the semiconductor wafer at a second temperature that is lower than the first temperature; and a grinding device that grinds the second surface of the semiconductor wafer to which the first support is bonded.

A substrate bonding method according to an aspect of the present invention is a substrate bonding method for semiconductor wafer having a first support bonded to a first surface thereof at a first temperature via a first adhesive, the method including bonding a second support to a second surface, which is on an opposite side to a first surface of a semiconductor wafer, at a second temperature that is lower than a first temperature, via a second adhesive.

### Advantageous Effects of the Invention

According to an aspect of the present invention, the adhesion is low between the second support and the semiconductor wafer, and it is thus possible to prevent the two from adhering together too firmly. As a result, it is possible to prevent the formation of residues of the second adhesive on the semiconductor wafer when debonding the second support from the semiconductor wafer. Furthermore, the second support is bonded to the second surface of the semiconductor wafer via the second adhesive at the second temperature, which is lower than the first temperature at which the first support is bonded to the first surface of the semiconductor wafer via the first adhesive. It is thus possible to prevent the first adhesive from softening when bonding the second support to the second surface, and prevent bonding failure of the first support.

### BRIEF DESCRIPTION OF THE DRAWINGS

FIG. 1 is a diagram showing an example of a substrate bonding device and a substrate processing system according to an embodiment.

FIG. 2A is a diagram showing an example of a laminate.

FIG. 2B is a diagram showing an example of a laminate.

FIG. 3 is a diagram showing an example of the substrate bonding device according to the embodiment.

FIG. 4 is a flowchart showing an example of a substrate bonding method according to the embodiment.

FIG. 5 is a flowchart showing an example of the substrate bonding method according to the embodiment, following FIG. 4.

FIG. 6 is a diagram showing a state of a first laminate being transferred into the substrate bonding device.

FIG. 7 is a diagram showing a state of the first laminate being sandwiched between a first plate and a second plate.

FIG. 8 is a diagram showing a state of a second laminate being sandwiched between the first plate and the second plate.

FIG. 9 is a diagram showing an example of a substrate bonding device and a substrate processing system according to a modified example.

### DESCRIPTION OF EMBODIMENTS

The following describes an embodiment of the present invention, with reference to the drawings. However, the invention is not limited to the following description. In the drawings, some parts may be omitted for the purpose of clearly describing the embodiment. Also, the scale is adjusted as necessary, such as by enlarging or emphasizing certain parts, so the sizes, shapes, dimensions, and other features may differ from those of the actual product.

In the following drawings, an XYZ Cartesian coordinate system is used to describe the directions in each drawing. In the XYZ coordinate system, the plane that is parallel to a horizontal plane is defined as an XY plane. In this XY plane, the direction parallel to the direction of transferring a semiconductor wafer W or a laminate 200 including a semiconductor wafer W is denoted as an X direction, and the direction orthogonal to the X direction is denoted as a Y direction. Furthermore, the direction perpendicular to the XY plane is denoted as Z direction (height direction). For each of the X direction, the Y direction, and the Z direction, description is made with a definition in which a direction indicated by an arrow is the positive (+) direction and a direction opposite to the direction indicated by the arrow is the negative (−) direction.

### Substrate Bonding Device, Substrate Processing System

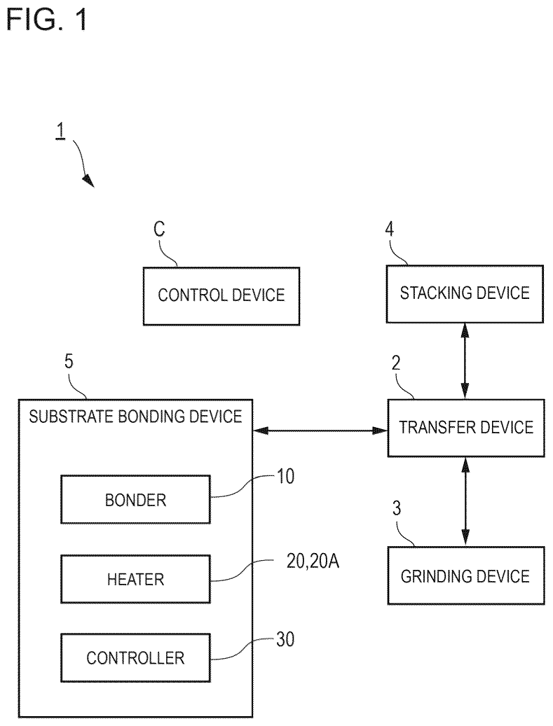

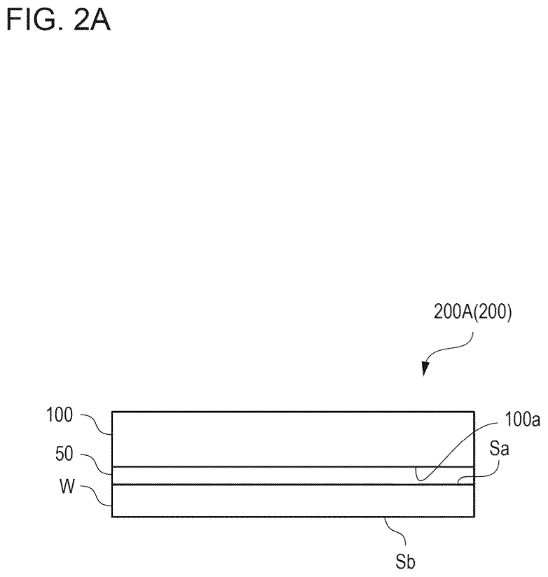

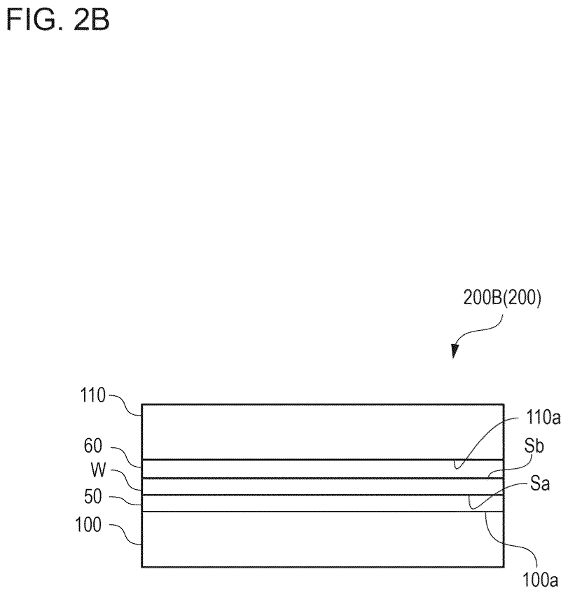

A substrate bonding device 5 and a substrate processing system 1 according to the embodiment will be described. FIG. 1 is a diagram showing an example of the substrate bonding device 5 and the substrate processing system 1 according to the embodiment. The substrate processing system 1 includes the substrate bonding device 5. The substrate processing system 1 executes steps of: stacking a first support 100 on a first surface Sa of a semiconductor wafer W; bonding the first support 100 to the semiconductor wafer W; grinding a second surface Sb, which is on the opposite side to the first surface Sa; stacking a second support 110 on the second surface Sb; and bonding the second support 110 to the second surface Sb. The semiconductor wafer W (see FIG. 2) is, for example, a substrate having a circular shape in plan view (as viewed from the Z direction). The semiconductor wafer W has circuit electrodes, electronic circuits, and other components formed on the first surface Sa (see FIG. 2).

The first support 100 and the second support 110 (see FIG. 2) are plate-shaped members used to support the semiconductor wafer W. The first support 100 and the second support 110 only need to have sufficient strength to prevent damage or deformation of the semiconductor wafer W during processes such as thinning, transferring, and mounting of the semiconductor wafer W. For example, materials such as glass plates and silicon wafers are used for the first support 100 and the second support 110.

The first support 100 and the second support 110 may be made of the same material, or different materials may be used. The first support 100 and the second support 110 are, for example, circular in shape in plan view (as viewed from the Z direction). The first support 100 and the second support 110 may have the same diameter as the semiconductor wafer W, a larger diameter than the semiconductor wafer W, or a smaller diameter than the semiconductor wafer W. The first support 100 and the second support 110 may have the same thickness or may have different thicknesses.

As shown in FIG. 1, the substrate processing system 1 includes a transfer device 2, a grinding device (polishing device) 3, a stacking device 4, a substrate bonding device 5, and a control device C. The control device C comprehensively controls the operation of each device in the substrate processing system 1. However, the operation of each device in the substrate processing system 1 may be performed manually by, for example, an operator instead of being controlled by the control device C.

The transfer device 2 transfers a semiconductor wafer W or a laminate 200 including the semiconductor wafer W (see FIG. 2). For example, the transfer device 2 transfers the laminate 200 between the stacking device 4 and the substrate bonding device 5. The transfer device 2 transfers the laminate 200 between the substrate bonding device 5 and the grinding device 3. Also, the transfer device 2 transfers the laminate 200 between the grinding device 3 and the stacking device 4. The transfer device 2 may be of any configuration capable of transferring the semiconductor wafer W or the laminate 200. For example, the transfer device 2 may be configured to use a robot arm to suction the upper face side or the lower face side of the semiconductor wafer W or the laminate 200 and transfer it. The transfer device 2 may use different (separate) transfer mechanisms for a first laminate 200A and a second laminate 200B, which will be described later.

The grinding device 3 grinds (polishes) the second surface Sb of the semiconductor wafer W in the laminate 200, reducing (thinning) the semiconductor wafer W to a predetermined thickness. For example, the laminate 200 to be ground is transferred into the grinding device 3 by the transfer device 2. The grinding device 3 grinds the second surface Sb of the semiconductor wafer W, which is the backside of the transferred laminate 200, using, for example, a grinding pad (polishing pad, or grinder). This grinding process is performed after the first support 100 is bonded to the first surface Sa of the semiconductor wafer W. The details of the grinding device 3 will be described later.

The stacking device 4 forms the laminate 200 (hereinafter, referred to as “first laminate 200A”) by stacking the first surface Sa of the semiconductor wafer W and a bonding surface 100a of the first support 100 in the vertical direction, with a first adhesive 50 therebetween. FIG. 2A is a diagram showing an example of the first laminate 200A. The first surface Sa of the semiconductor wafer W has formed thereon circuit electrodes, electronic circuits, and other components, for example. At least one of the first surface Sa of the semiconductor wafer W and the bonding surface 100a of the first support 100 is preliminarily applied with the first adhesive 50. Therefore, by stacking the first support 100 onto the first surface Sa of the semiconductor wafer W, a layer of the first adhesive 50 is formed in the first laminate 200A between the first surface Sa of the semiconductor wafer W and the bonding surface 100a of the first support 100.

The stacking device 4 forms the laminate 200 (hereinafter, referred to as “second laminate 200B”) by vertically stacking the second surface Sb of the semiconductor wafer W, which has been ground by the grinding device 3, onto the bonding surface 110a of the second support 110. FIG. 2B is a diagram showing an example of the second laminate 200B. At least one of the second surface Sb of the semiconductor wafer W and the bonding surface 110a of the second support 110 is preliminarily applied with a second adhesive 60. Therefore, by stacking the second support 110 onto the second surface Sb of the semiconductor wafer W, a layer of the second adhesive 60 is formed in the second laminate 200B between the second surface Sb of the semiconductor wafer W and the bonding surface 110a of the second support 110.

The configuration of the stacking device 4 is arbitrary, allowing for the application of any device that can align the semiconductor wafer W with the first support 100, or the semiconductor wafer W (first laminate 200A) with the second support 110, to stack the two together. In the first laminate 200A, the semiconductor wafer W and the first support 100 are stacked together, so that the two are lightly bonded together via the first adhesive 50. In the second laminate 200B, the semiconductor wafer W and the second support 110 are stacked together, so that the two are lightly bonded together via the second adhesive 60.

The stacking device 4 is arranged next to the substrate bonding device 5, for example. This configuration allows for the rapid transfer of the first laminate 200A or the second laminate 200B, formed by the stacking device 4, to the substrate bonding device 5. Also, the transfer device 2 may include a dedicated transfer unit to transfer the first laminate 200A or the second laminate 200B from the stacking device 4 to the substrate bonding device 5, distinct from the transfer unit that transfers the semiconductor wafer W, the first support 100, or the second support 110 to the stacking device 4.

The first adhesive 50 uses, for example, an adhesive that dissolves at a first temperature or higher and has thermoplastic or thermosetting properties. For example, adhesives containing various adhesive materials commonly known in the relevant field, such as acrylic-based, novolac-based, epoxy-based, hydrocarbon-based, polyimide-based, and elastomer adhesives, as well as resist materials with thermoplastic properties or those that exhibit thermoplastic properties after curing, can be used as the first adhesive 50. The second adhesive 60 uses, for example, an adhesive that dissolves at a second temperature, which is lower than the first temperature, or higher and has thermoplastic or thermosetting properties. For example, the adhesives containing the above various adhesive materials commonly known in the relevant field, as well as resist materials with thermoplastic properties or those that exhibit thermoplastic properties after curing, can be used as the second adhesive 60. The second adhesive 60 may either differ from the first adhesive 50 or be the same adhesive.

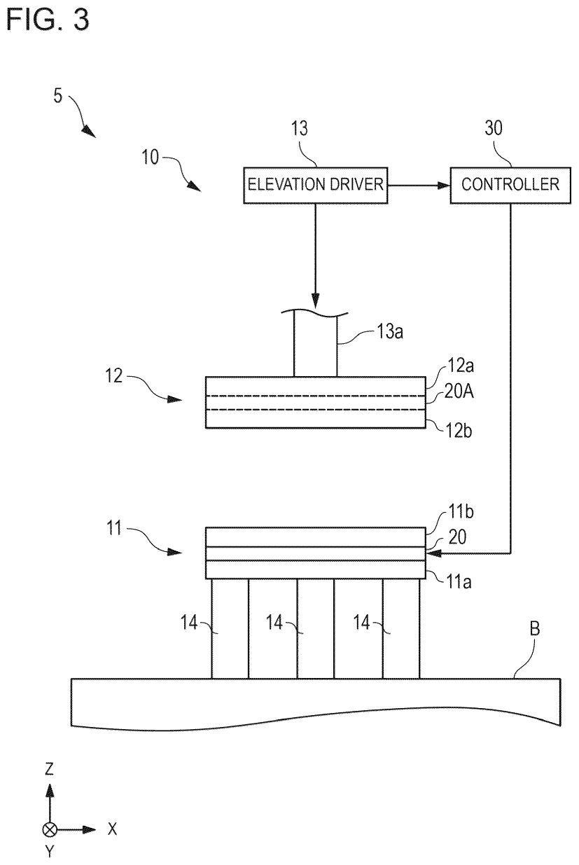

FIG. 3 is a diagram showing an example of the substrate bonding device 5 according to the embodiment. As shown in FIG. 1 and FIG. 2, the substrate bonding device 5 includes a bonder 10, heaters 20, 20A, and a controller 30. The substrate bonding device 5 may, for example, be an atmospheric open-type device that operates under atmospheric conditions, or it may have a chamber that houses the bonder 10 and the heater 20. If the substrate bonding device 5 has a chamber, it may be configured to maintain a vacuum atmosphere (or a reduced-pressure atmosphere) inside the chamber using a vacuum pump, or it may be configured to supply a predetermined gas (such as an inert gas) to create a specific gaseous atmosphere within the chamber.

The bonder 10 includes a first plate 11, a second plate 12, and an elevation driver 13. On the first plate 11, the laminate 200 transferred into the substrate bonding device 5 is placed. The first plate 11 may include lift pins for transferring the laminate 200 from or to the transfer device 2. These lift pins may support the laminate 200 at upper ends thereof, elevate during the transfer of the laminate 200, and retract into the first plate 11 during the pressing of the laminate 200. The first plate 11 is circular in shape and has an outer diameter larger than that of the laminate 200 in plan view. However, the shape of the first plate 11 is not limited to a circular shape and may, for example, be quadrangular (square or rectangular), oval, elliptical, or other shapes.

The first plate 11 includes a support plate 11a and a base plate 11b. The heater 20 is provided between the support plate 11a and the base plate 11b. The first plate 11 is supported by pillars 14 provided on the lower face of the support plate 11a. The support plate 11a is a plate-shaped member formed from a material such as metal, resin, ceramics, or other materials. The pillar 14 is arranged in multiple locations on the lower face of the support plate 11a and supports the support plate 11a on a base B of the substrate bonding device 5 with high rigidity. The multiple pillars 14 are arranged, for example, at the center portion of the lower face of the support plate 11a and at multiple locations that surround the center portion, distributing the pressing force applied to the support plate 11a in a balanced manner.

The laminate 200 is placed on the upper face of the base plate 11b. The upper face of the base plate 11b serves as the contact surface with the laminate 200. Therefore, the upper face of the base plate 11b is preferably highly flat with low surface roughness (or mirror polished). For the base plate 11b, a ceramic plate formed in a plate shape from ceramics is used, for example. However, the base plate 11b is not limited to being a ceramic plate, and may be a metal or resin plate. The heater 20 will be described later in conjunction with the heater 20A of the second plate 12.

The second plate 12 is arranged directly above the first plate 11. The second plate 12 is circular in shape and has an outer diameter larger than that of the laminate 200 in plan view. However, the shape of the second plate 12 is not limited to a circular shape and may, for example, be quadrangular (square or rectangular), oval, elliptical, or other shapes. The shape of the second plate 12 is not limited to being the same as that of the first plate 11, and it may differ from the shape of the first plate 11, for example, by having an outer diameter larger than that of the first plate 11.

The second plate 12 includes a support plate 12a and a base plate 12b. The heater 20 may be provided between the support plate 12a and the base plate 12b. The second plate 12 is supported in a suspended state by an elevation shaft 13a provided on the upper face of the support plate 12a. The elevation shaft 13a is raised and lowered by driving the elevation driver 13. The second plate 12 is raised and lowered together with the elevation shaft 13a as the elevation shaft 13a is raised and lowered.

In the example shown in FIG. 3, one elevation shaft 13a is provided in the center portion of the upper face of the support plate 12a. However, the present invention is not limited to this configuration, and multiple elevation shafts 13a may be provided on the upper face side of the support plate 12a. In such a case, the multiple elevation shafts 13a may be provided at the center portion of the upper face of the support plate 12a and at multiple locations surrounding the center portion, so as to apply the pressing force to the second plate 12 in a balanced manner. When multiple elevation shafts 13a are provided, an elevation driver 13 may be provided individually for each of the multiple elevation shafts 13a, or a single elevation driver 13 may be used to raise and lower all the multiple elevation shafts 13a collectively.

The support plate 12a is a plate-shaped member formed from a material such as metal, resin, ceramics, or other materials. The lower face of the base plate 12b comes into contact with the laminate 200 when the second plate 12 is lowered. The lower face of the base plate 12b may be flat or may be shaped as a convex surface that slopes from the center portion of the lower face toward the outer peripheral edge. For the base plate 12b, a ceramic plate formed in a plate shape from ceramics is used, for example. However, the base plate 12b is not limited to being a ceramic plate, and may be a metal or resin plate.

The second plate 12 is lowered by the elevation driver 13, thereby pressing the laminate 200 placed on the first plate 11 downward. The pressing force applied to the laminate 200 is set preliminarily, and the controller 30 controls the elevation driver 13 to press the laminate 200 with the preliminarily set pressing force. The laminate 200 is sandwiched between the first plate 11 and the second plate 12 under the predetermined pressing force, whereby the semiconductor wafer W and the first support 100 (or the semiconductor wafer W and the second support 110) are bonded together under temperature conditions provided by the heaters 20, 20A described later.

The heaters 20, 20A heat the laminate 200. The heaters 20, 20A are, for example, hot plates having a heating mechanism (heat source) such as electric heating wires inside. In the example shown in FIG. 2, the heater 20 is provided in the first plate 11, and the heater 20A is provided in the second plate 12. However, the present invention is not limited to this configuration, and it may also be possible for either of the heaters 20 or 20A to be absent. The heaters 20, 20A heat the first laminate 200A, which is sandwiched between the first plate 11 and the second plate 12, at the first temperature. With this configuration, in the first laminate 200A, the first adhesive 50 melts from the heat applied at the first temperature, thereby bonding together the first surface Sa of the semiconductor wafer W and the bonding surface 100a of the first support 100. For example, the first temperature is preferably 160° C. or higher, more preferably 175° C. or higher, and even more preferably 200° C. or higher. As the first adhesive 50, for example, a resist containing a thermoplastic hydrocarbon-based resin is used.

The heater 20 heats the second laminate 200B, which is sandwiched between the first plate 11 and the second plate 12, at the second temperature. With this configuration, in the second laminate 200B, the second adhesive 60 melts from the heat applied at the second temperature, thereby bonding together the second surface Sb of the semiconductor wafer W and the bonding surface 110a of the second support 110. Here, the second temperature is lower than the first temperature. Therefore, even if the second laminate 200B is heated at the second temperature, the first adhesive 50 does not melt because it does not reach the first temperature. For example, the second temperature ranges from 40° C. to 150° C. As the second adhesive 60, for example, a resist containing an epoxy-based resin that exhibits thermoplastic properties after curing is used.

The controller 30 controls the operations of the elevation driver 13 and the heaters 20, 20A. The controller 30 controls the temperature of the heat application performed by the heaters 20, 20A, that is, the temperature used to heat the laminate 200. For example, the controller 30 may include a processor such as a CPU (Central Processing Unit) or an MPU (Micro Processing Unit) and a non-volatile or volatile semiconductor memory (for example, RAM (Random Access Memory), ROM (Read Only Memory), flash memory, EPROM (Erasable Programmable Read Only Memory), or EEPROM (Electrically Erasable Programmable Read Only Memory)). For example, the controller 30 may be a microcontroller such as an MCU. The controller 30 may be configured as a part of the control device C of the substrate processing system 1.

### Substrate Bonding Method

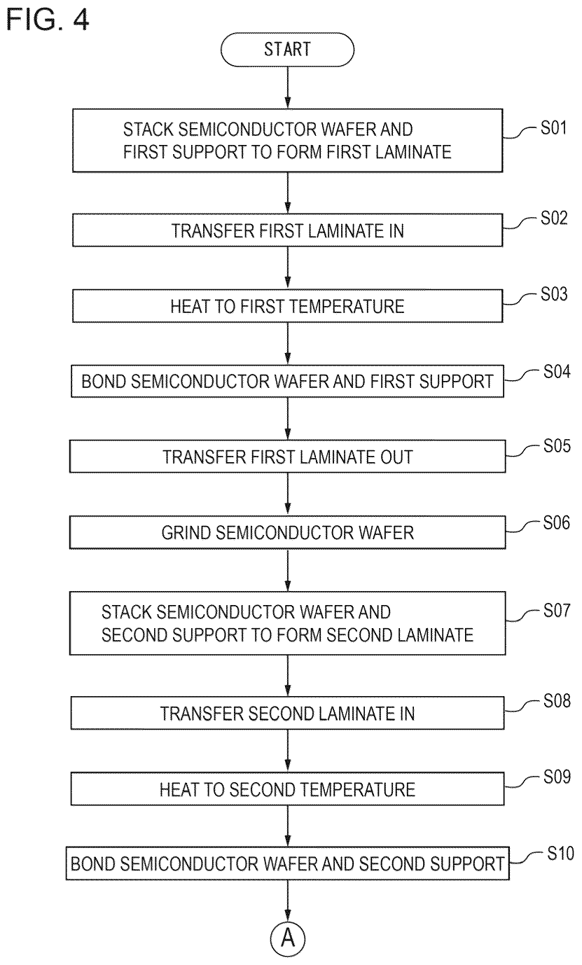

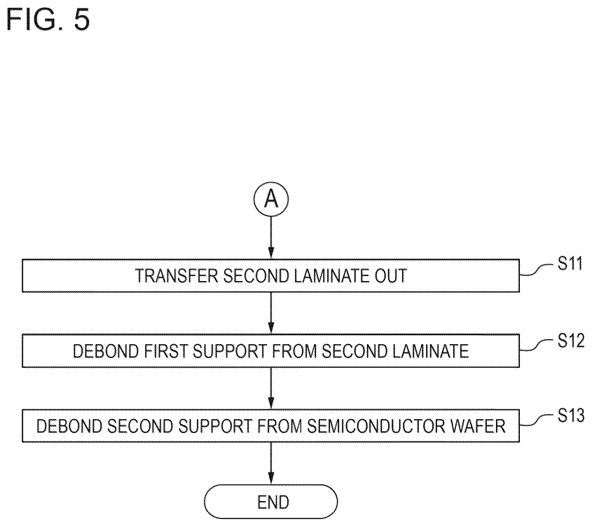

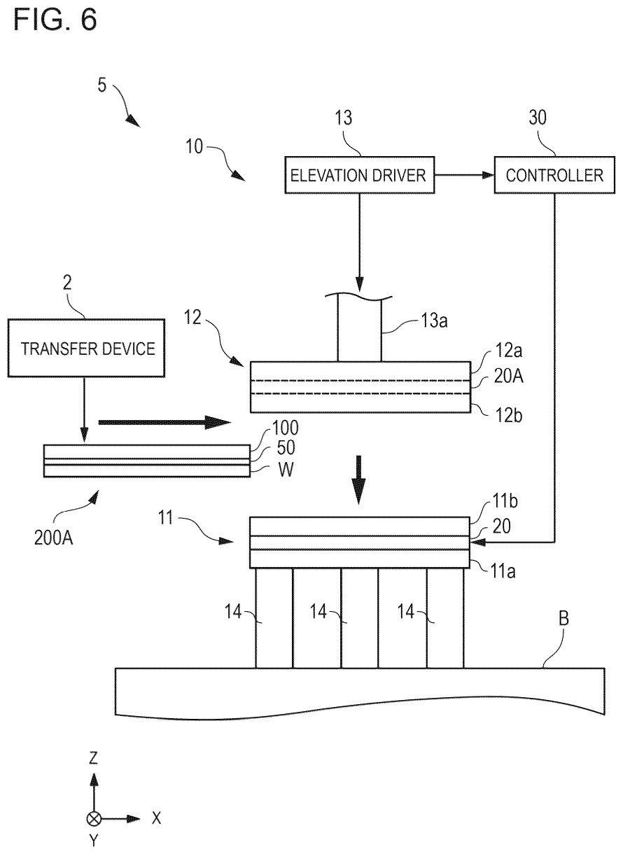

Next, a substrate bonding method according to the embodiment will be described. FIG. 4 is a flowchart showing an example of the substrate bonding method according to the embodiment. FIG. 5 is a flowchart showing an example of the substrate bonding method according to the embodiment, following FIG. 4. The substrate bonding method shown in FIG. 4 and FIG. 5 is executed, for example, according to instructions from the controller 30 or the control device C of the substrate processing system 1. FIG. 6 to FIG. 8 are diagrams showing an example of the operation of the substrate bonding device 5. In FIG. 6 to FIG. 8, some descriptions have been simplified to facilitate understanding of the movement of each component.

First, as shown in FIG. 4, the semiconductor wafer W and the first support 100 are stacked together to form a first laminate 200A (Step S01). Step S01 is performed by the stacking device 4. Prior to Step S01, the first adhesive 50 is applied to one or both of the first surface Sa of the semiconductor wafer W and the bonding surface 100a of the first support 100, for example, using a coating device. The first adhesive 50 is applied to the entire first surface Sa of the semiconductor wafer W or the entire bonding surface 100a of the first support 100. However, the first adhesive 50 may also be applied at interval or sporadically to the first surface Sa or the bonding surface 100a. After the first adhesive 50 is applied, the semiconductor wafer W and the first support 100 are each transferred into the stacking device 4 by the transfer device 2.

The stacking device 4 forms the first laminate 200A by stacking the first surface Sa of the semiconductor wafer W and the bonding surface 100a of the first support 100 in the vertical direction, with a first adhesive 50 therebetween. For example, the stacking device 4 aligns the first support 100 that is transferred thereinto first, and raises and holds the aligned first support 100. At this time, the first support 100 is held so as to orient the bonding surface 100a downward. Next, the semiconductor wafer W is transferred into the stacking device 4 by the transfer device 2. At this time, the semiconductor wafer W is transferred into the stacking device 4 so as to orient the first surface Sa of the semiconductor wafer W upward.

The stacking device 4 aligns the semiconductor wafer W that has been transferred thereinto. After having aligned the semiconductor wafer W, the stacking device 4 lowers the first support 100 or raises the semiconductor wafer W to form the first laminate 200A by stacking the first surface Sa of the semiconductor wafer W and the bonding surface 100a of the first support 100 in the vertical direction, with a first adhesive 50 therebetween. Upon forming the first laminate 200A, the first laminate 200A is transferred into the substrate bonding device 5 by the transfer device 2 (Step S02).

FIG. 6 is a diagram showing a state of the first laminate 200A being transferred into the substrate bonding device 5. In Step S02, the transfer device 2 transfers the first laminate 200A while maintaining suction on either its upper face or lower face, for example, as shown in FIG. 6, and moves the first laminate 200A into the interior of the substrate bonding device 5. Next, the transfer device 2 places the first laminate 200A on the first plate 11. The transfer device 2 lowers the first laminate 200A and places the first laminate 200A on the base plate 11b of the first plate 11. In the case where the first plate 11 is provided with lift pins, the transfer device 2 transfers the first laminate 200A onto the upper ends of the lift pins. Subsequently, the first laminate 200A is placed on the base plate 11b as the lift pins are lowered.

Then, the first laminate 200A is heated to the first temperature (Step S03). In Step S03, the controller 30 drives the heaters 20, 20A to heat the first laminate 200A to the first temperature. The first temperature is set according to the first adhesive 50. For example, a memory storage (not shown in the drawings) included in the controller 30 stores a correspondence between the first adhesive 50 and the first temperature. The controller 30 acquires information about the first adhesive 50 being used, and acquires the first temperature for the first adhesive 50 from the memory storage. The controller 30 controls the heaters 20, 20A on the basis of values output from a temperature sensor not shown in the drawings to ensure that the acquired first temperature is reached. Prior to Step S03, a preliminary heating may be performed using the heaters 20, 20A to heat the first plate 11 and the second plate 12, for example, to the first temperature.

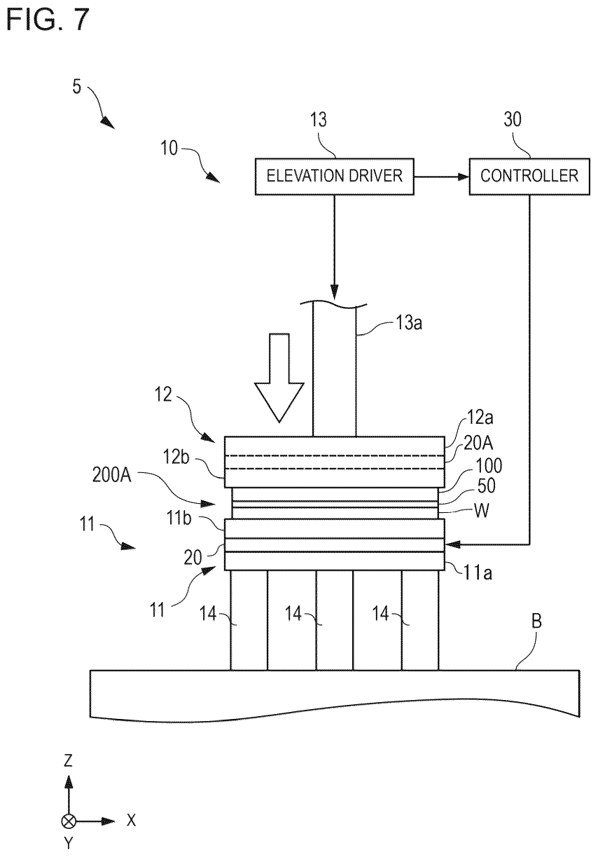

Subsequently, the semiconductor wafer W and the first support 100 are bonded together (Step S04). FIG. 7 is a diagram showing a state of the first laminate 200A being sandwiched between the first plate 11 and the second plate 12. In Step S04, the substrate bonding device 5 bonds the first surface Sa of the semiconductor wafer W and the bonding surface 100a of the first support 100 together at the first temperature, as shown in FIG. 7. In Step S04, the controller 30 drives the elevation driver 13 to lower the second plate 12 together with the elevation shaft 13a, and presses the first laminate 200A on the first plate 11 downward with a predetermined pressing force.

That is to say, the first laminate 200A is sandwiched between the base plate 11b of the first plate 11 and the base plate 12b of the second plate 12 under the predetermined pressing force. At this time, the first laminate 200A is heated to the first temperature by the heaters 20, 20A. As a result, the first adhesive 50 is heated to the first temperature through the first support 100 and the semiconductor wafer W, causing it to melt, and the semiconductor wafer W and the first support 100 are bonded together by the pressing force applied by the second plate 12. The duration of the pressing force application performed by the second plate 12 is preliminarily set depending on the first adhesive 50 or the first temperature. The controller 30 uses a timer or the like not shown in the drawings to determine whether or not the preliminarily set period of time has elapsed.

Subsequently, the first laminate 200A is transferred out of the substrate bonding device 5 by the transfer device 2 (Step S05). In Step S05, the transfer device 2 lifts the first laminate 200A from the first plate 11 while maintaining suction on either its upper face or lower face, and then transfers the first laminate 200A out of the substrate bonding device 5. Then, the first laminate 200A is transferred to the grinding device 3 by the transfer device 2.

The semiconductor wafer W of the first laminate 200A is ground by the grinding device 3 (Step S06). In Step S06, the grinding device 3 grinds the second surface Sb of the semiconductor wafer W in the first laminate 200A to reduce the thickness of the semiconductor wafer W. The grinding device 3 includes, for example, a shaft, a rotary head, and a grinding pad. The shaft can be rotated by a driver not shown in the drawings about a rotation axis parallel to the vertical direction. The rotary head is provided at the lower end of the shaft and rotates together with the shaft. The grinding pad is removably attached to the lower face of the rotary head.

The first laminate 200A is arranged with the second surface Sb of the semiconductor wafer W facing the grinding pad. The grinding device 3 rotates the grinding pad attached to the rotary head about the rotation axis while gradually lowering the grinding pad and moving it horizontally relative to the first laminate 200A. The semiconductor wafer W of the first laminate 200A is ground by the grinding pad to a desired thickness. At this time, since the semiconductor wafer W is bonded to the first support 100 by the first adhesive 50, cracking and other issues are prevented during grinding. The grinding amount of the semiconductor wafer W is determined by the amount of descent of the grinding pad.

Next, once the grinding of the semiconductor wafer W by the grinding device 3 is completed, the transfer device 2 transfers the first laminate 200A out of the grinding device 3 and transfers it into the stacking device 4. The transfer device 2 also transfers the second support 110 into the stacking device 4. Subsequently, the stacking device 4 stacks the semiconductor wafer W of the first laminate 200A and the second support 110 together to form a second laminate 200B (Step S07). Step S07 is performed by the stacking device 4. Prior to Step S07, the second adhesive 60 is applied to one or both of the second surface Sb of the semiconductor wafer W and the bonding surface 110a of the second support 110, for example, using a coating device. The second adhesive 60 is applied at intervals or sporadically to the second surface Sb of the semiconductor wafer W or the bonding surface 110a of the second support 110. However, the second adhesive 60 may be applied to the entire surface of the second surface Sb or the bonding surface 110a. After the second adhesive 60 is applied, the first laminate 200A and the second support 110 are each transferred into the stacking device 4 by the transfer device 2.

The stacking device 4 forms the second laminate 200B by stacking the second surface Sb of the semiconductor wafer W and the bonding surface 110a of the second support 110 in the vertical direction, with the second adhesive 60 therebetween. For example, the stacking device 4 aligns the second support 110 that is transferred thereinto first, and raises and holds the aligned second support 110. At this time, the second support 110 is held so as to orient the bonding surface 110a downward. Next, the first laminate 200A is transferred into the stacking device 4 by the transfer device 2. At this time, the first laminate 200A is transferred into the stacking device 4 so as to orient the second surface Sb of the semiconductor wafer W of the first laminate 200A upward.

The stacking device 4 aligns the first laminate 200A that has been transferred thereto. After having aligned the first laminate 200A, the stacking device 4 lowers the first support 100 or raises the first laminate 200A to form the second laminate 200B by stacking the second surface Sb of the semiconductor wafer W and the bonding surface 110a of the second support 110 in the vertical direction, with the second adhesive 60 therebetween. Upon forming the second laminate 200B, the second laminate 200B is transferred into the substrate bonding device 5 by the transfer device 2 (Step S08).

In Step S08, the transfer device 2 transfers the second laminate 200B while maintaining suction on either its upper face or lower face, and moves the second laminate 200B into the interior of the substrate bonding device 5. Next, the transfer device 2 lowers the second laminate 200B and places the second laminate 200B on the base plate 11b of the first plate 11.

In the case where the first plate 11 is provided with lift pins, the transfer device 2 transfers the second laminate 200B onto the upper ends of the lift pins. Subsequently, the second laminate 200B is placed on the base plate 11b as the lift pins are lowered. In the above description, the second laminate 200B is placed on the first plate 11 with the second support 110 on the upper side, however, it may be placed on the first plate 11 with the first support 100 on the upper side.

Then, the second laminate 200B is heated to the second temperature (Step S09). In Step S09, the controller 30 drives the heaters 20, 20A to heat the first laminate 200A to the second temperature that is lower than the first temperature. The second temperature is set according to the second adhesive 60. For example, the above memory storage (not shown in the drawings) included in the controller 30 stores a correspondence between the second adhesive 60 and the second temperature. The controller 30 acquires information about the second adhesive 60 being used, and acquires the second temperature for the second adhesive 60 from the memory storage. The controller 30 controls the heaters 20, 20A on the basis of values output from a temperature sensor not shown in the drawings to ensure that the acquired second temperature is reached. Prior to Step S09, a preliminary heating may be performed using the heaters 20, 20A to heat the first plate 11 and the second plate 12, for example, to the second temperature.

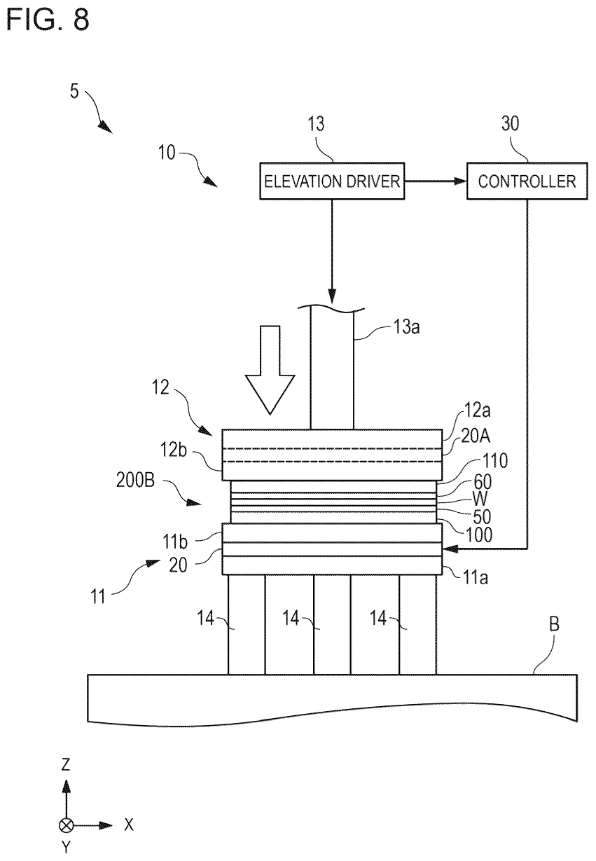

Subsequently, the semiconductor wafer W and the second support 110 are bonded together (Step S10). FIG. 8 is a diagram showing a state of the second laminate 200B being sandwiched between the first plate 11 and the second plate 12. In Step S10, the substrate bonding device 5 bonds the second surface Sb of the semiconductor wafer W and the bonding surface 110a of the second support 110 together at the second temperature, as shown in FIG. 8. In Step S10, the controller 30 drives the elevation driver 13 to lower the second plate 12 together with the elevation shaft 13a, and presses the second laminate 200B on the first plate 11 downward with a predetermined pressing force.

That is to say, the second laminate 200B is sandwiched between the base plate 11b of the first plate 11 and the base plate 12b of the second plate 12 under the predetermined pressing force. At this time, the second laminate 200B is heated to the second temperature by the heaters 20, 20A. As a result, the second adhesive 60 is heated to the second temperature through the first support 100, the second support 110, and the semiconductor wafer W, causing it to melt, and the semiconductor wafer W and the second support 110 are bonded together by the pressing force applied by the second plate 12. Moreover, since the second temperature is lower than the first temperature, the first adhesive 50 does not soften or melt even when heated to the second temperature. Therefore, the first adhesive 50 can maintain the adhesion between the semiconductor wafer W and the first support 100. The duration of the pressing force application performed by the second plate 12 is preliminarily set depending on the second adhesive 60 or the second temperature. The controller 30 uses a timer or the like not shown in the drawings to determine whether or not the preliminarily set period of time has elapsed. It should be noted that if the second adhesive 60 and the first adhesive 50 are the same adhesive, the semiconductor wafer W and the second support 110 are bonded at a second temperature that is lower than a first temperature used when bonding the semiconductor wafer W and the first support 100. As a result, as with the above description, the softening or melting of the first adhesive 50 is prevented, thereby preventing bonding failure of the first support 100 to the semiconductor wafer W.

Next, as shown in FIG. 5, the second laminate 200B is transferred out of the substrate bonding device 5 by the transfer device 2 (Step S11). In Step S11, the transfer device 2 lifts the second laminate 200B from the first plate 11 while maintaining suction on either its upper face or lower face, and then transfers the second laminate 200B out of the substrate bonding device 5.

Subsequently, after Step S11, as a first debonding process, the adhesive properties of the first adhesive 50 are reduced, or the first adhesive 50 is dissolved by irradiating the second laminate 200B with light or immersing it in a specific solvent, to thereby debond the first support 100 from the second laminate 200B (Step S12). The first debonding process of Step S12 is performed using, for example, a light irradiation device, an immersion device, or a debonding device. After Step S12, for example, a dicing process is performed to cut the semiconductor wafer W into individual chips. This dicing process is performed using, for example, a dicing device. Next, after the first debonding process, as a second debonding process, the semiconductor wafer W (chips) is physically separated from the second support 110, thereby debonding the second support 110 from the semiconductor wafer W (chips) (Step S13). The second debonding process of Step S13 is performed by physically separating the semiconductor wafer W (chips) from the second support 110 using, for example, a picking device or the like. In other words, the second support 110 is physically separated from the semiconductor wafer W. Since the adhesion is low between the second support 110 and the semiconductor wafer W, it is possible to prevent the formation of residues of the second adhesive 60 on the semiconductor wafer W (chips). The series of processes is completed when the semiconductor wafer W (chips) has been physically separated from the second support 110.

As a comparative example, when the second support 110 is bonded to the second surface Sb of the semiconductor wafer W at a heating temperature of 160° C. or higher, corresponding to the first temperature, the second support 110 and the semiconductor wafer W are bonded together firmly, and during the second debonding process described above, residues of the second adhesive 60 may be formed on the semiconductor wafer W. In the present embodiment, the semiconductor wafer W and the second support 110 are bonded at a low second temperature in the range of 40° C. to 150° C. Therefore, compared to the comparative example above, the adhesion between the second support 110 and the semiconductor wafer W is lower, thus preventing firm adhesion therebetween. As a result, in the second debonding process of Step S13 described above, it is possible to prevent the formation of residues of the second adhesive 60 on the semiconductor wafer W.

As described above, according to the present embodiment, the second support 110 is bonded to the second surface Sb of the semiconductor wafer W via the second adhesive 60 at the second temperature that is lower than the first temperature, at which the first support 100 is bonded to the first surface Sa of the semiconductor wafer W via the first adhesive 50. It is thus possible to prevent the first adhesive 50 from softening when bonding the second support 110 to the second surface Sb, and prevent bonding failure of the first support 100.

### Modified Example

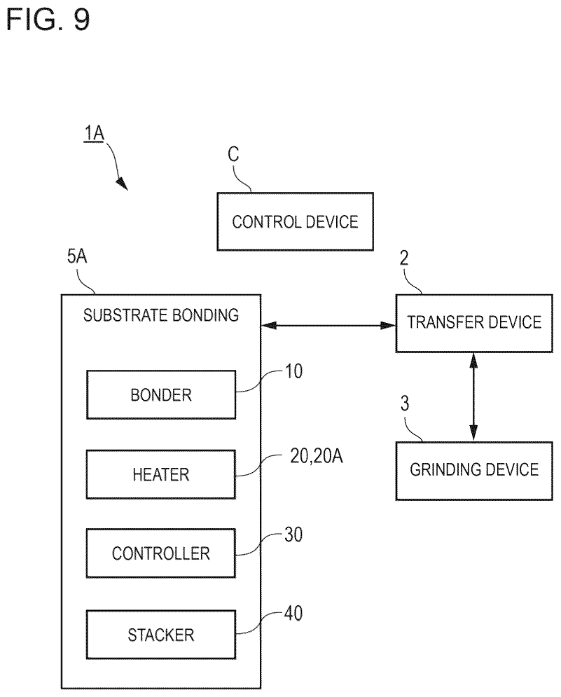

A substrate bonding device 5A and a substrate processing system 1A according to a modified example will now be described. FIG. 9 is a diagram showing an example of the substrate bonding device 5A and the substrate processing system 1A according to the modified example. In the embodiment described above, the substrate processing system 1 has been described with an example configuration in which the stacking device 4 and the substrate bonding device 5 are included as separate devices. However, the present invention is not limited to this configuration. The functions of the stacking device 4 and the substrate bonding device 5 may be integrated into a single device. In FIG. 9, the configurations similar to those in the above embodiment are assigned with the same reference signs and the descriptions thereof are omitted or simplified.

As shown in FIG. 9, the substrate processing system 1A includes a transfer device 2, a grinding device (polishing device) 3, a substrate bonding device 5A, and a control device C. The substrate bonding device 5A includes a bonder 10, heaters 20, 20A, a controller 30, and a stacker 40. That is to say, the substrate bonding device 5A includes a stacker 40 having the same functions as the stacking device 4 of the substrate processing system 1 described above.

The stacker 40, for example, supports the first support 100, which is transferred into the substrate bonding device 5A first, in the space between the first plate 11 and the second plate 12. The semiconductor wafer W, transferred into the substrate bonding device 5A next, is then raised using lift pins, thereby bonding the semiconductor wafer W and the first support 100 together to form the first laminate 200A. Next, the lift pins are lowered to place the first laminate 200A onto the first plate 11. Then, the second plate 12 is lowered, and the semiconductor wafer W and the first support 100 are bonded together at the first temperature.

Also, the stacker 40, for example, supports the second support 110, which is transferred into the substrate bonding device 5A first, in the space between the first plate 11 and the second plate 12. The first laminate 200A, transferred into the substrate bonding device 5A next, is then raised using lift pins, thereby bonding the first laminate 200A and the second support 110 together to form the second laminate 200B. Subsequently, the lift pins are lowered to place the second laminate 200B onto the first plate 11. Then, the second plate 12 is lowered, and the semiconductor wafer W and the second support 110 are bonded together at the second temperature.

In this way, in the present modified example, similar to the embodiment described above, the second support 110 is bonded to the second surface Sb of the semiconductor wafer W via the second adhesive 60 at the second temperature that is lower than the first temperature. It is thus possible to prevent the softening of the first adhesive 50 during the bonding of the second support 110 to the second surface Sb. Furthermore, the substrate processing system 1A according to the present modified example includes the substrate bonding device 5A, which includes the stacker 40, and this eliminates the need for the stacking device 4 of the embodiment described above. Thus, it is possible to reduce the footprint of the substrate processing system 1A.

The embodiment and modified example of the invention have been described above. However, the technical scope of the present invention is not limited to the the embodiment and modified example described above, and various modifications may be made without departing from the gist of the invention. Also, it is apparent to those skilled in the art that various modifications or improvements can be added to the above embodiment and modified example, and the technical scope of the present invention also encompasses such modifications or improvements. One or more of the requirements described in the above embodiment and modified example may be omitted in some cases, and one or more of the requirements described in the above embodiments and modified example may be combined where appropriate. The order of executing procedures shown in the embodiment and modified example can be implemented in an arbitrary order unless the result of the previous procedure is used in the following procedure. While operations in the above embodiment and modified example have been described with expressions such as “first”, “next”, and “subsequently” for the sake of convenience, the operations need not always be implemented in that order.

### DESCRIPTION OF REFERENCE SIGNS

1, 1A: Substrate processing system
3: Grinding device
5, 5A: Substrate bonding device
10: Bonder
11: First plate
12: Second plate
20, 20A: Heater
50: First adhesive
60: Second adhesive
100: First support
100a: Bonding surface
110: Second support
110a: Bonding surface
W: Semiconductor wafer

1. A substrate bonding device comprising
a bonder that bonds a second support to a second surface, which is on an opposite side to a first surface a semiconductor wafer, via a second adhesive, with the first surface of the semiconductor wafer having a first support bonded thereto at a first temperature via a first adhesive, and
a heater that heats one or both of the second support and the semiconductor wafer at a second temperature that is lower than the first temperature.

2. The substrate bonding device according to claim 1,
wherein the first surface of the semiconductor wafer is provided with a circuit electrode.

3. The substrate bonding device according to claim 1 or 2,
wherein the bonder includes a first plate that comes in contact with a surface on an opposite side to a surface of the first support to which the semiconductor wafer is bonded, and a second plate that comes in contact with a surface on an opposite side to a surface of the second support to which the semiconductor wafer is bonded, and
wherein the heater is provided on one or both of the first plate and the second plate.

4. The substrate bonding device according to claim 1 or 2,
wherein the second adhesive is a thermoplastic resist.

5. The substrate bonding device according to claim 1 or 2,
wherein the second adhesive is provided at intervals on a bonding surface of the second support.

6. The substrate bonding device according to claim 1 or 2,
wherein the second adhesive is different from the first adhesive.

7. The substrate bonding device according to claim 1 or 2,
wherein the bonder bonds the second surface of the semiconductor wafer to the second support under atmospheric conditions.

8. The substrate bonding device according to claim 1 or 2,
wherein the second temperature ranges from 40° C. to 150° C.

9. The substrate bonding device according to claim 1 or 2,
wherein the heater heats one or both of the second support and the semiconductor wafer for a certain period of time before bonding the second surface of the semiconductor wafer to the second support.

10. The substrate bonding device according to claim 9,
wherein the heater performs heating at the second temperature for a certain period of time before bonding the second surface of the semiconductor wafer to the second support.

11. The substrate bonding device according to claim 1 or 2,
wherein the bonder is capable of boding the first support to the first surface of the semiconductor wafer via the first adhesive, and
wherein the heater heats one or both of the first support and the semiconductor wafer to the first temperature.

12. The substrate bonding device according to claim 11,
wherein the first adhesive is provided on an entirety of a bonding surface of the first support.

13. A substrate processing system comprising
a grinding device that grinds the second surface of the semiconductor wafer to which the first support is bonded, and
a substrate bonding device according to claim 1 or 2.

14. A substrate bonding method for a semiconductor wafer having a first support bonded to a first surface thereof at a first temperature via a first adhesive, the substrate boding method comprising
bonding a second support to a second surface, which is on an opposite side to a first surface of the semiconductor wafer, at a second temperature that is lower than a first temperature.
